(19) United States
(12) Patent Application Publication
(10) Pub. No.: US 2013/0187286 A1
(43) Pub. Date: Jul. 25, 2013

(54) LEAD FRAMELESS HERMETIC CIRCUIT PACKAGE

(71) Applicants: Richard Schneider, Livonia, MI (US); Eric Eymard, Aiguilhe (FR)

(72) Inventors: Richard Schneider, Livonia, MI (US); Eric Eymard, Aiguilhe (FR)

(21) Appl. No.: 13/556,760

(22) Filed: Jul. 24, 2012

Related U.S. Application Data
(60) Provisional application No. 61/511,350, filed on Jul. 25, 2011.

(51) Int. Cl. H01L 23/48

(52) U.S. Cl. CPC H01L 23/481
USPC 257/774

(57) ABSTRACT

A open cavity semiconductor chip package that is leadless and does not have a metal lead frame as in conventional packages. The absence of a lead frame minimizes leakage paths and allows the novel package to be more readily fabricated as a hermetic package. A dual sided insulative or dielectric film is employed as the base interconnect between a semiconductor chip and outside contacts. Electrical connection from the top side of the film to the bottom side of the film is made through conductive micro-vias. The semiconductor chip is mounted on a paddle in a central opening in the film and wire bonded to pads on the film. After mounting of the chip, a cover or lid is attached to the film to encapsulate the assembly and maintain hermeticity of the package.

### STATEMENT REGARDING FEDERALLY SPONSORED RESEARCH OR DEVELOPMENT

N/A

### BACKGROUND OF THE INVENTION

This application relates to circuit packages for semiconductor chips and more particularly to circuit packages that are leadless and hermetic.

Semiconductor circuits or chips are typically mounted inside circuit packages to protect the chip or die and to facilitate electrical, mechanical and thermal connection of the chip to printed circuit boards and the like. A typical circuit package includes a base or flange, a protective insulating housing and leads extending through the housing. The leads are electrically bonded directly or by wires to contacts on the chip.

While many different configurations of circuit packages are known, they are not wholly satisfactory for providing hermetic sealing of a chip contained within the package.

In a conventional package having a lead frame, the leads extend through a plastic wall from outside the package to a cavity inside the package. Leakage can occur along these lead paths, thereby affecting the hermeticity of the package.

### BRIEF SUMMARY OF THE INVENTION

The entire contents of Provisional Application Ser. No. 61/511,350 filed Jul. 25, 2011 are hereby incorporated by reference herein.

The present invention provides an open cavity semiconductor chip package that is leadless and does not have a metal lead frame as in conventional packages. The absence of a lead frame minimizes leakage paths and allows the novel package to be more readily fabricated as a hermetic package.

According to the invention, a dual sided insulative or dielectric film is employed as the base interconnect between a semiconductor chip and outside contacts. Electrical connection from the top side of the film to the bottom side of the film is made through conductive micro-vias. The semiconductor chip is mounted on a paddle in a central opening in the film and wire bonded to pads on the film. After mounting of the chip, a cover or lid is attached to the film to encapsulate the assembly and maintain hermeticity of the package. The package can be configured in a variety of known package configurations such as the QFN form. The number and sizes of the lead patterns can vary to suit particular package configurations and intended applications. Packages in accordance with the invention can be provided in reel form, in sheets or as individual pieces for further downstream assembly.

### BRIEF DESCRIPTION OF THE SEVERAL VIEWS OF THE DRAWINGS

The invention will be more fully understood from the following detailed description taken in conjunction with the accompanying drawings, in which:

FIG. 1 is a cut away pictorial view of one embodiment of the invention;

FIG. 2 is a cut away pictorial view of a second embodiment of the invention;

FIG. 3 is a cut away pictorial view showing a cover or lid in place on a package according to the invention;

FIG. 4 is a pictorial view on a sheet or panel containing an array of package units configurations according to the invention;

FIG. 5 is an exploded pictorial view showing a package array and corresponding lid array;

FIG. 6 is a plan view of a continuous strip form of package units embodying the invention;

FIG. 7 is a pictorial view of another embodiment of the invention; and

FIG. 8 is a cut away view of the package of FIG. 7.

### DETAILED DESCRIPTION OF THE INVENTION

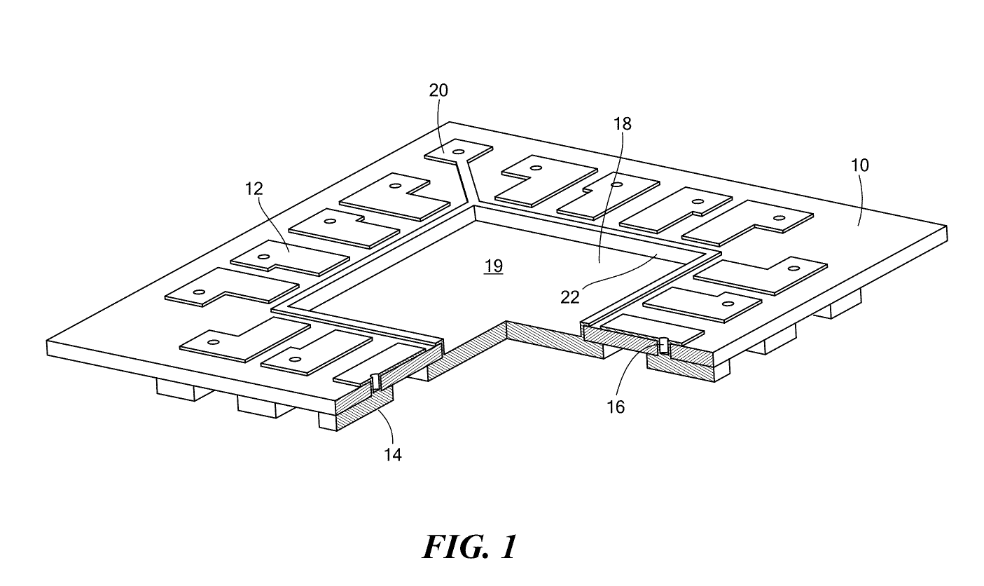

One embodiment of the novel package is shown in FIG. 1. An insulative film 10 has pads 12 disposed about the top side of the film and which are electrically connected to contacts 14 on the bottom side of the film by conductive micro-vias 16 extending through the film. The insulated base film can be formed from a variety of materials including FR-4 or related circuit board materials, polyimide, polyester, LCP, PEEK or other plastic, ceramic or other insulative materials. A central area or window 18 in the film has a copper or other metal surface 19 which is electrically connected to one or more pads 20 by means of a plated sidewall 22. The film 10 in one embodiment has a copper surface on each side which is selectively processed to form the pads and central paddle area. In one version, the top copper surface is chemically etched away in the central area and the dielectric film material is laser ablated to expose the lower copper surface. The exposed copper surface can be plated up to a desired thickness. In another version, the central area is cut away and a bottom copper surface is adhered to the film by a suitable adhesive. A semiconductor chip (not shown) can be bonded to the conductive surface 19 in the central area 18 and wire bonded to respective pads 12. In the FIG. 1 embodiment, the central area is sometimes referred to as a down set paddle area. The invention is not limited to a down set configuration.

In an alternative version, the central area has an insulating surface rather than a conductive surface as described above. A semiconductor chip is bonded to the insulating surface and can be wire bonded to respective bonding pads.

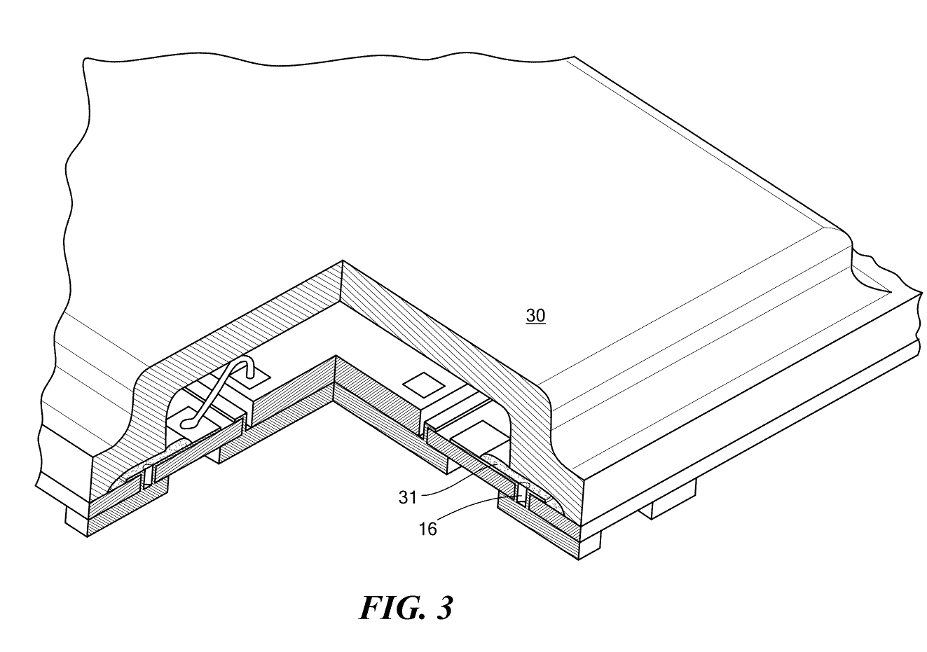

A lid 30, shown in FIG. 3, is disposed on the topside of the film covering the pads 12 and central area and is bonded to the film to seal the package. Bonding can be accomplished with epoxy or other adhesive, or by welding or brazing, for example. The lid can be formed of a variety of materials to suit the operational circumstances. In one embodiment, the lid is a plastic material. In another embodiment, the lid can be metal or a metalized plastic. For optical applications, such as for use with light emitting and/or light sensing devices, the lid can have a window or lens in the central area thereof for permitting light transmission into and/or out of the package.

In FIG. 3, the lid is bonded to the film about the periphery thereof. The lid has a recessed area 31 which extends over the vias 16. The recessed area 31 can be filled with an epoxy or other suitable encapsulating material to provide a seal over the confronting end of the via holes and to serve as a sealant against possible leak paths through the vias.

The connection pads 12 on the top side of the film are typically formed by etching of a copper plating or copper sheet disposed on the top side of the film. The contacts 14 on the bottom side of the film are also typically formed by etching of a copper plating or copper sheet bonded to the bottom side of the film. The vias formed in the film are plated through to provide a conductive connection between the pads 12 and contacts 14 on respective sides of the insulated film 10. Alternatively, the vias can be formed with conductive paste which is screened and cured in the via holes. The formation of vias in an insulated substrate and the provision of plated through or otherwise conductive holes is per se known in the circuit board art.

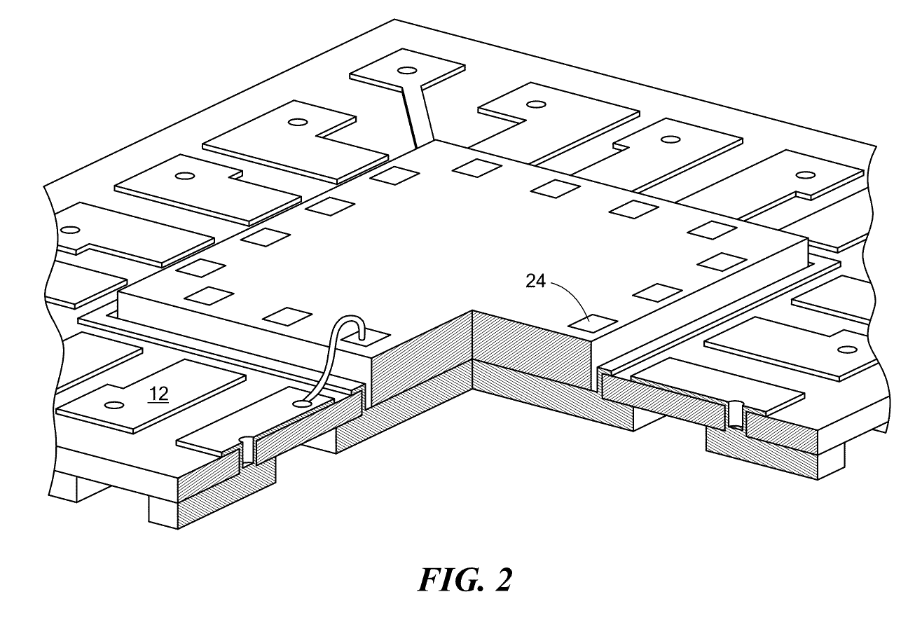

Another embodiment is shown in FIG. 2 which is similar to FIG. 1, except that the central area has down set die pads 24 disposed about the periphery of the central area for respective wire bonding to pads 12.

The contacts 14 on the bottom side of the film are disposed over and are in electrical contact with the bottom ends of the conductive vias. Leak paths through the vias are blocked by the presence of the overlying contacts 14 which isolates the vias from the external environment.

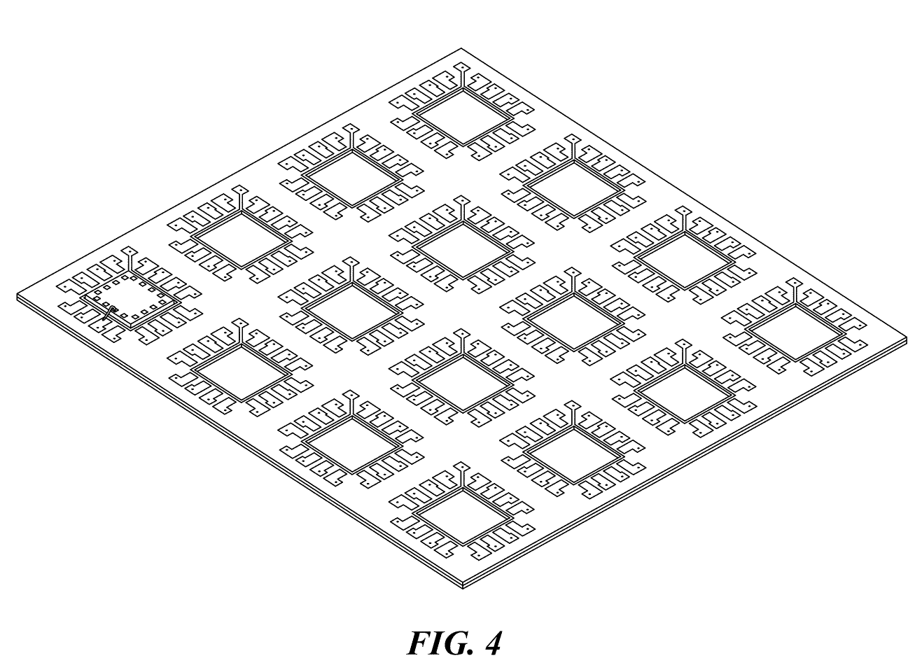

For high volume manufacturing, the package is typically fabricated in multiple units. FIG. 4 shows a panel having an array of package units provided thereon. Each of the units is as described above. The individual units can be separated from the panel before installation and wire bonding of chips thereon, or after the chips are bonded to the respective package units.

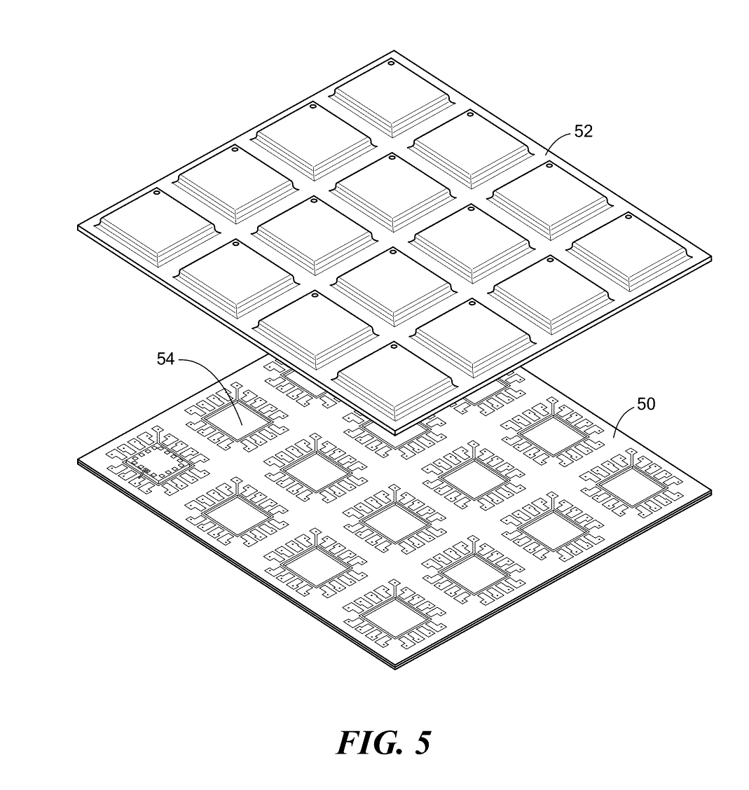

FIG. 5 shows a lid panel 52 having an array of lid units. The lid panel can be bonded to the package panel 50 after the chips have been attached to the respective package units. Individual lidded package units 54 are later cut or sawed into individual piece parts. Individual lids can also be provided and bonded to individual package units.

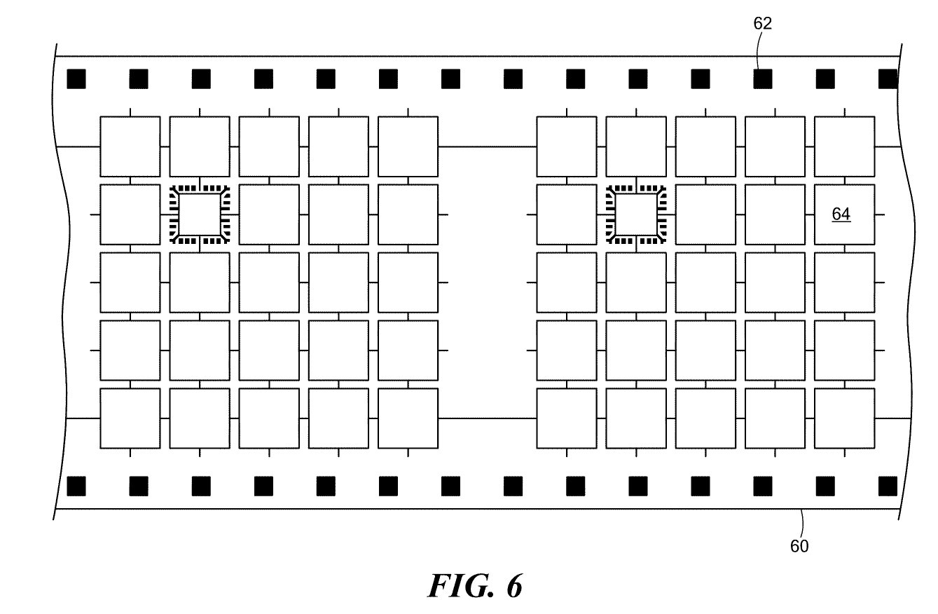

FIG. 6 shows and array of package units 64 one continuous strip 60 having sprocket holes 62 which can be employed with automated assembly equipment known in the art for rapid and automatic assembly of chips into each of the package units.

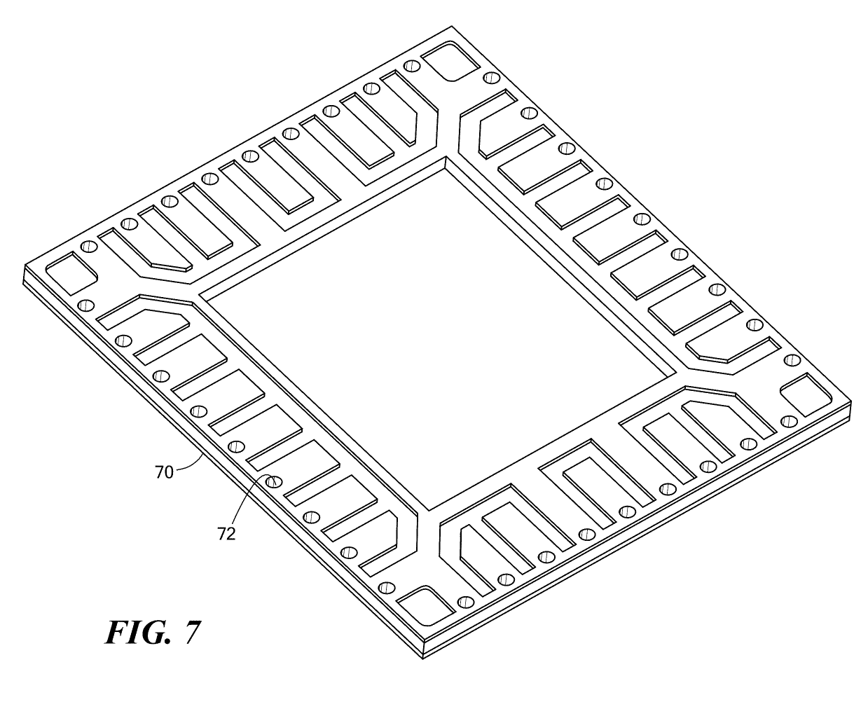

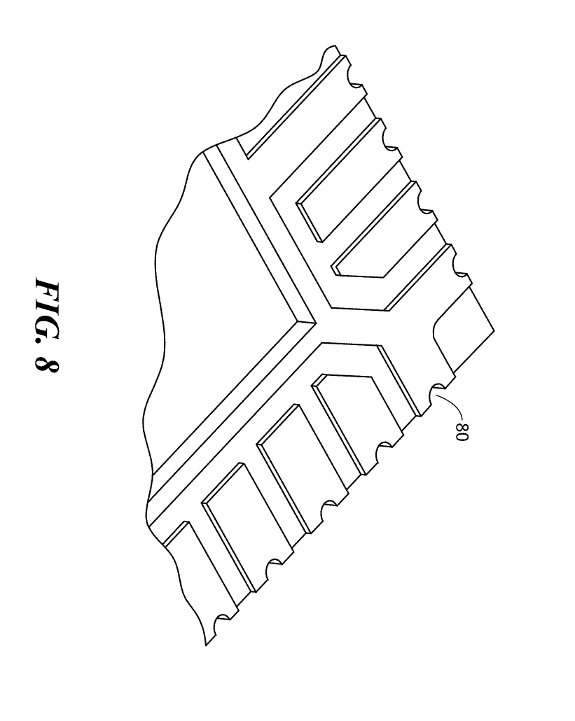

A further embodiment is shown in FIG. 7 in which the via holes 72 are positioned outside of the sealed cavity area and outside of the lid. Any leakage through the via paths do not affect the hermeticity of the sealed package as the paths are outside of the sealed area. When individual packages are cut from a sheet, as in FIG. 5, the package can be cut midway through the vias 72 to provide half cylinders 80 about the periphery of the film as shown in FIG. 8. These half cylinders provide the electrical connection between paths on the upper film surface and connections on the bottom film surface.

The invention is not to be limited by what has been particularly shown and described except as indicated by the spirit and true scope of the appended claims.

What is claimed is:

1. A circuit package comprising:
an insulative film defining a central open area having a conductive surface on which an electronic chip or device is mountable;
the film having:
a first surface on which a plurality of connection pads are disposed;
a second surface opposite to the first surface on which a plurality of external contacts are disposed;
a plurality of conductive vias extending through the film in positions to be in electrical contact with respective connection pads on the first surface of the film and corresponding external contacts on the second surface of the film; and
the external contacts each covering the respective vias to which it is electrically contacted to isolate the via from the external environment and minimize leakage paths through the via.

2. The circuit package of claim 1 wherein the sidewalls of the central open area of the film have a conductive coating thereon electrically connected to the conductive surface of the central open area;
at least one connection pad on the first surface of the film being electrically connected to the conductive coating of the sidewalls.

3. The circuit package of claim 1 wherein the first surface of the film has a mounting area about the periphery of the film on which a lid can be bonded.

4. The circuit package of claim 3 including a lid having a peripheral surface bondable to the mounting area of the first surface of the film.

5. The circuit package of claim 1 wherein a plurality of circuit package units are disposed on a sheet and separable into individual packages.

6. The circuit package of claim 5 wherein a plurality of lid units are disposed on a sheet and bondable to the sheet containing the plurality of circuit package units;
each package and lid unit being separable from the respective sheets to provide an individual package and lid.

7. The circuit package of claim 4 wherein the lid includes a recessed area inward of the mounting area and disposed over the vias when the lid is mounted on the film;
the recessed area configured to accommodate a sealant therein disposed over the vias.

8. The circuit package of claim 3 wherein the vias are disposed outside the mounting area of the film on which a lid is bondable.

9. The circuit package of claim 8 wherein the film is cut along a center line of the vias to provide partial vias around the periphery of the package.
